(19) United States
(12) Patent Application Publication
(10) Pub. No.: US 2024/0237249 A1
(43) Pub. Date: Jul. 11, 2024

(54) Hinge System for Swing Out Panel

(71) Applicant: Hoffman Enclosures Inc., Anoka, MN (US)

(72) Inventors: William Anderson, Blaine, MN (US); Rony Khalife, Coon Rapids, MN (US); Asrar Khan, Fridley, MN (US); Ahmed Sheikh, Minneapolis, MN (US); Nicole Stevens, Anoka, MN (US)

(21) Appl. No.: 18/406,681

(22) Filed: Jan. 8, 2024

Related U.S. Application Data
(60) Provisional application No. 63/478,807, filed on Jan. 6, 2023.

(51) Int. Cl. H05K 7/14; E05D 3/02; E05D 5/06

(52) U.S. Cl. CPC H05K 7/14; E05D 3/02; E05D 5/06; E05Y 2201/218; E05Y 2201/224; E05Y 2900/60

(57) ABSTRACT

An enclosure can include an enclosure body and a door secured by an external hinge. A swing out panel can be secured by an internal hinge. The internal hinge can include a support body and a pivot body that can prevent the inward rotation of the swing out panel. The internal hinge can be secured at the external hinge. A retainer clip can include a mounting portion secured onto a swing out panel and a clip portion to engage a door opening.

### CROSS-REFERENCE TO RELATED APPLICATIONS

This application claims priority to U.S. provisional patent application No. 63/478,807, filed Jan. 6, 2023, the entirety of which is incorporated herein by reference.

### BACKGROUND

Enclosures are often used in various industries to conceal and retain electrical components. In some cases, enclosures can include multiple panels to support components, as may increase the overall utility of the enclosure.

### SUMMARY

In some examples, an enclosure for electrical components can include an enclosure body that defines an interior volume and a door opening. The door is secured to the enclosure body with an external hinge to be pivotally movable relative to the door opening and the external hinge being positioned outside of the interior volume. The enclosure can also include a swing out panel and an internal hinge that rotatably supports the swing out panel for movement between an installed orientation in which the swing out panel is fully within the interior volume and a swung out orientation in which the panel extends at least partly out of the door opening. The internal hinge is positioned within the interior volume and is secured to the enclosure via the external hinge.

In some examples, an internal hinge to support a swing out panel of an enclosure can include a support body including a support portion configured to be rigidly secured to an external hinge of the enclosure with the support portion extending substantially in parallel with a side wall of the enclosure. The internal hinge can also include a pivot body pivotally supported by the support body. The pivot body can include an extension portion and a connection portion that are connected by a bend and the connection portion can extend from the bend to support the swing out panel. The bend can be arranged to contact the support body to stop rotation of the pivot body in a first direction, with the connection portion of the pivot body extending substantially perpendicular to the support portion of the support body.

In some examples, a retainer clip for a swing out panel of an enclosure can include a mounting portion secured to the swing out panel, an extension portion that extends away from the mounting portion, and a clip portion that can engage the enclosure body to secure the swing out panel in the installed orientation. The clip portion can include a first recess that opens in a first direction to engage the enclosure body and a handle portion that provides a handle for manual movement of the swing out panel.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a front isometric view of an enclosure with a swing out panel according to an embodiment of the invention, with a door of the enclosure in an open configurations and the swing out panel in a first swung out orientation;

FIG. 2A is a front isometric view of an internal hinge for the swing out panel of FIG. 1;

FIG. 2B is a top plan sectional view of a pivot body of the internal hinge of FIG. 2A.

FIG. 3 is a sectional partial rear view of the enclosure of FIG. 1, showing the internal hinge of FIG. 2 secured to an external hinge of the enclosure.

FIG. 4A is an isometric detail view of the hinge of FIG. 2 supporting the swing out panel of FIG. 1 in a second swung-out orientation.

FIG. 4B is a top plan, partly schematic, detail view of the hinge of FIG. 2 arranged to support the swing out panel of FIG. 1 in an installed orientation.

FIG. 5 is a perspective view of a retainer clip for the swing out panel of FIG. 1.

FIG. 6 is an isometric detail view of the retainer clip of FIG. 5 securing the swing out panel of FIG. 1 in an installed orientation.

FIG. 7 is a trimetric view of another embodiment of a retainer clip for the swing out panel of FIG. 1.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Enclosure panels can provide support for various components (e.g., cable managers, servers or other electronics, LCD screens or other user interfaces, etc.). Using only a rear enclosure panel, it may be difficult to provide enough space to support all of the various electrical equipment and other components within an enclosure, or to present more frequently accessed components (e.g., user interfaces) in an ergonomic or otherwise appropriately accessible fashion. Accordingly, some enclosures can include multiple panels, including a rear panel that is rigidly secured to the enclosure frame and a front panel that can be hinged between an installed (e.g., service) orientation and a swung-out (or open) orientation. In an installed (or service) orientation, for example, a front panel can be oriented fully within an interior volume of the enclosure, in front of and generally in parallel with a rear wall or rear panel of the enclosure. In a swung-out orientation, the panel can be rotated to extend at least partly out of the interior volume of the enclosure and thereby provide improved access to other components within the interior volume (e.g., electronics supported on a rear panel).

Conventional designs for enclosures and exterior door hinges generally do not provide for an easy conversion of an enclosure to include swing out panels. For example, adding a swing out panel to an existing enclosure under conventional approaches may include drilling additional holes in the sidewall of the enclosure to accommodate an interior hinge for the swing out panel. Further, additional parts and equipment may need to be installed to ensure that the swing out panel is properly limited in its range of motion. For example, additional distinct stops may need to be installed to limit the pivoting range of a swing out panel and thereby prevent undesired contact between the swing out panel and other components, or between the larger enclosure and various components that are supported on the swing out panel. In addition, conventional swing out panels may lack features to secure the swing out panel in an installed (or service) orientation or to assist users in easily opening the panel to a swung-out orientation.

Some examples disclosed herein can provide swing out panels, interior hinges, and retainer clips that can address the problems noted above, or various others associated with installation and use of swing out panels, in a wide variety of enclosures. For example, some interior hinges disclosed herein are configured to be secured to an enclosure using the same holes that anchor an exterior enclosure hinge (e.g., by being secured directly to the exterior enclosure hinge with common fasteners, to collectively secure both hinges to the enclosure). Accordingly, additional drill holes in an enclosure sidewall may not be required to add a swing out panel to an existing enclosure.

In some examples, an interior hinge includes a stop feature to control the range of motion of a swing out panel, including as can ensure that the swing out panel does not swing too far inwards or outwards. For example, some configurations can include a bent hinge body that can contact an enclosure side wall or other structure (e.g., another hinge body, or other pre-existing structures in the enclosure) to prevent a swing out panel from swinging past an installed orientation (e.g., past parallel with a rear panel) and thereby extending too far into an interior volume of the enclosure. Such hinges, in some examples, can also include angled configurations that can allow a swing out panel to be easily pivoted out of an enclosure so that the swing out panel itself does not block access to the interior of the enclosure via the door opening (e.g., is entirely clear of the door opening and an outward projection thereof).

In some examples, a retainer clip can additionally (or alternatively) provide a stop against rotation of a swing out panel, to prevent the swing out panel from rotating past a desired orientation (e.g., inward or outward). Such a clip can in some cases also serve as a handle for easy manual engagement of the swing out panel during installation, maintenance, or other operations. For example, one or more retainer clips can be configured to be secured to a free end of a swing out panel (e.g., on an opposite end of the panel from an internal hinge) and can include, respectively, a releasable retention end that can selectively and releasably secure the swing out panel in a closed position.

Generally, the features discussed above and below can collectively (or individually) help to increase the amount of usable or user-accessible support area of an enclosure, while utilizing a minimum amount of labor and materials. Other benefits will be also apparent to those of skill in the art in view of the detailed discussion below.

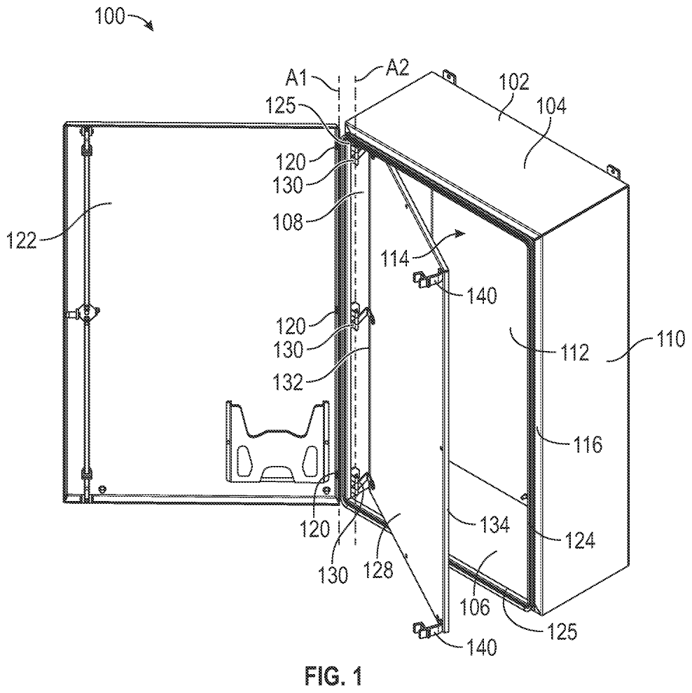

The concepts described herein can be practiced in various enclosures or enclosure system for various purposes (e.g., electrical system enclosure), as will be described below. FIG. 1 illustrates an enclosure 100 which includes an enclosure body 102. The enclosure body 102 includes a top wall 104, a bottom wall 106, side walls 108, 110, and a rear wall 112 defining an interior volume 114. The top wall 104 is disposed opposite of the bottom wall 106, and the side walls 108, 110 are disposed between the top wall 104 and the bottom wall 106 to form a door frame 116 that extends outside of and away from the interior volume 114 to define a door opening 124.

In some embodiments, the door opening 124 of the door frame 116 is indented along the side walls 108, 110 by a front offset 125. In some examples, the door opening 124 along the top and bottom walls 104, 106 can be set apart from the top and bottom walls 104, 106 by the front offset 125. Referring to FIG. 1, a first end of the front offset 125 extends substantially orthogonal from the side walls 108, 110 and a second end of the front offset 125 defines the door opening 124. Similarly, the first end of the front offset 125 may extend substantially orthogonal from the top and bottom walls 104, 106. In other words, the front offset 125 can define at least one side (e.g., all sides) of the door opening 124.

The enclosure 100 includes at least one external hinge 120 that hingedly connects to secure a door 122 to the enclosure body 102. Thus, the door 122 may be pivotally movable relative to the door opening 124, adjacent to the door frame 116. In some embodiments, the periphery of the door opening 124 may be smaller than the periphery of the door frame 116. In some embodiments, the periphery of the door opening 124 may be identical to the periphery of the door frame 116. In some embodiments, a gasket or other sealing media (not shown) may be installed on the enclosure body 102, at the door opening 124, to establish a sealed connection with the door 122.

Depending on the purpose of the enclosure 100, different materials may be used to form different parts of the enclosure body 102 and the door 122. In some embodiments, metallic materials (e.g., galvanized steel, stainless steel, aluminum, etc.) may be used to manufacture sheet metal to form the enclosure body 102 and the door 122. In some embodiments, plastic materials (e.g., ABS, PVC, PET, Nylon, etc.) can be used to form the enclosure body 102 and the door 122. Depending on the materials that forms the enclosure body 102, different methods may be applied to establish connection or bonding. For example, for the enclosure body 102 may be formed from sheet metal and the walls comprising enclosure body 102 can be welded along the edges between the vertices, although other methods may be used. For a plastic enclosure, adhesive bonding may be used, although other methods may be used. In some embodiments, the material of the enclosure body 102 and the door 122 may be different. Other components described below may be formed by similar materials as listed above.

As illustrated, the enclosure 100 is generally rectangular, with the side walls 108, 110 and the top and bottom walls 104, 106 parallel to each other, respectively, and perpendicular to the rear wall 112. In other examples, other configurations are possible, including enclosures with different numbers or orientations of walls, door openings, or other features.

Still with reference to FIG. 1, the enclosure 100 includes a swing out panel 128 that is hingedly connected to the side wall 108 by at least one internal hinge 130. In particular, in the example shown, multiple internal hinges 130 are secured to a fixed end 132 of the swing out panel 128 that is opposite a free end 134 of the swing out panel 128. As further detailed below, the internal hinges 130 can be secured, respectively, at corresponding external hinges 120 and can allow the panel 128 to swing easily and fully out of the door opening 124 and can also prevent the panel 128 from swinging too far into the enclosure (e.g., can stop the panel 128 in a parallel orientation with a plane of the door opening 124 or with the rear wall 112

The free end 134 can also include at least one retainer clip 140 in some examples. In some embodiments, the retainer clips 140 may be positioned at upper and lower vertices of the free end 134 as illustrated in FIG. 1, although retainer clips may be positioned at different locations in other examples. In some embodiments, a plurality of retainer clips 140 may be positioned along the edges of the swing out panel 128. In some embodiments, the plurality of retainer clips 140 may be positioned along the edges and the vertices of the swing out panel 128. The swing out panel 128 may be formed from same or different material with the enclosure body 102 or the door 122. As also discussed below, the retainer clip 140 (or the retainer clips 140) can help both to hold the panel 128 in a service orientation (e.g., substantially parallel to the rear wall 112 or the door opening 124) and to assist operators in swinging the panel 128 to a swung-out orientation.

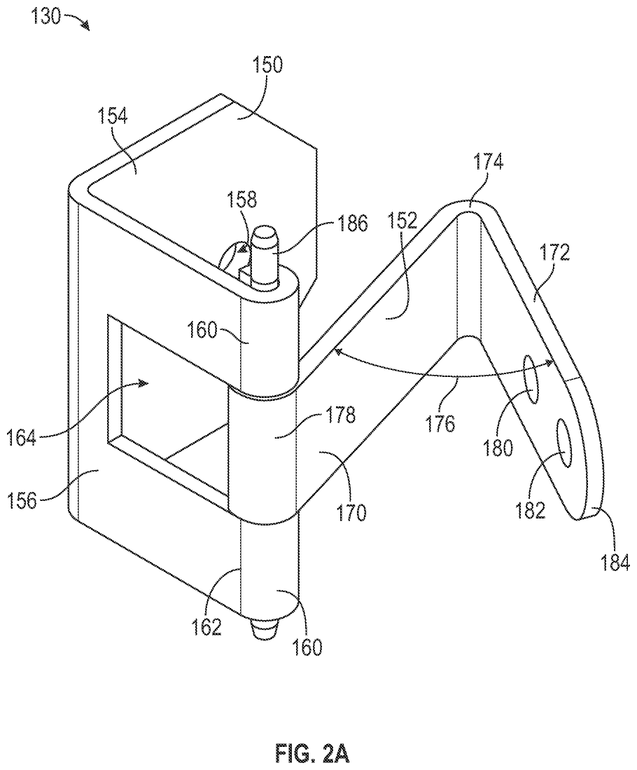

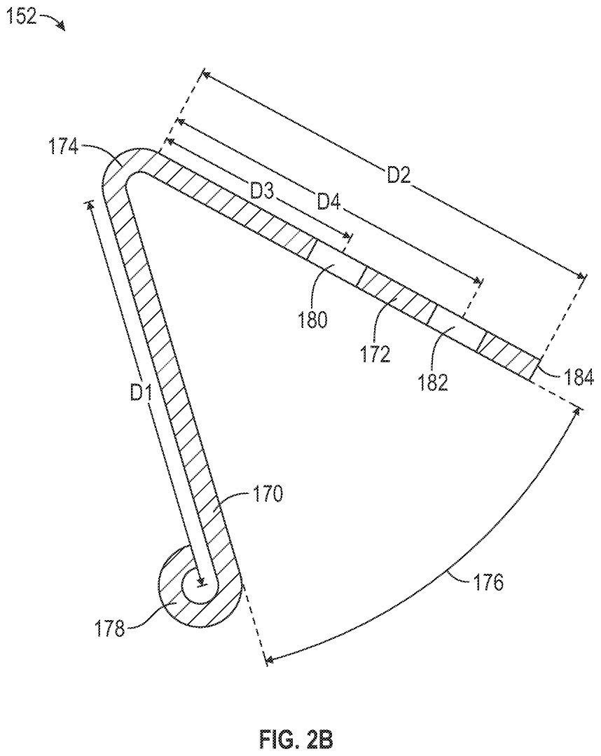

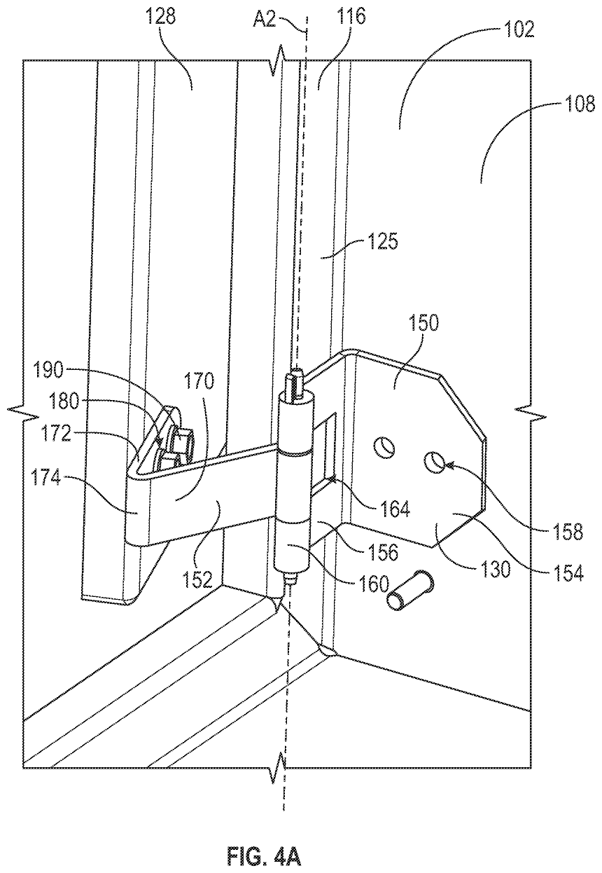

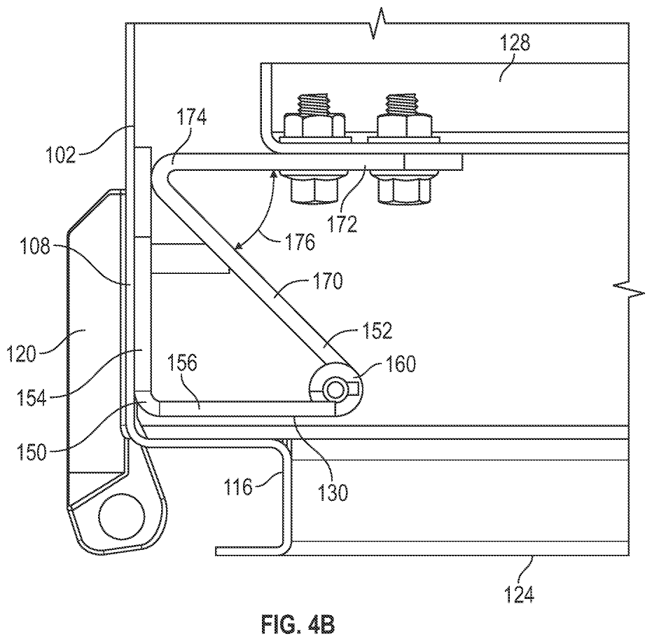

As mentioned herein, an internal hinge can include various shapes and configurations. FIGS. 2A-4B illustrate certain details of one example configuration of the internal hinge 130, to hingedly connect the swing out panel 128 to the enclosure 100. As noted above, the internal hinge 130 generally rotatably supports the swing out panel 128 for movement between an installed orientation, in which the swing out panel 128 is fully within the interior volume 114 (see FIG. 4B), and a swung-out orientation, in which the swing out panel 128 extends at least partly out of the door opening 124 (see FIG. 4A).

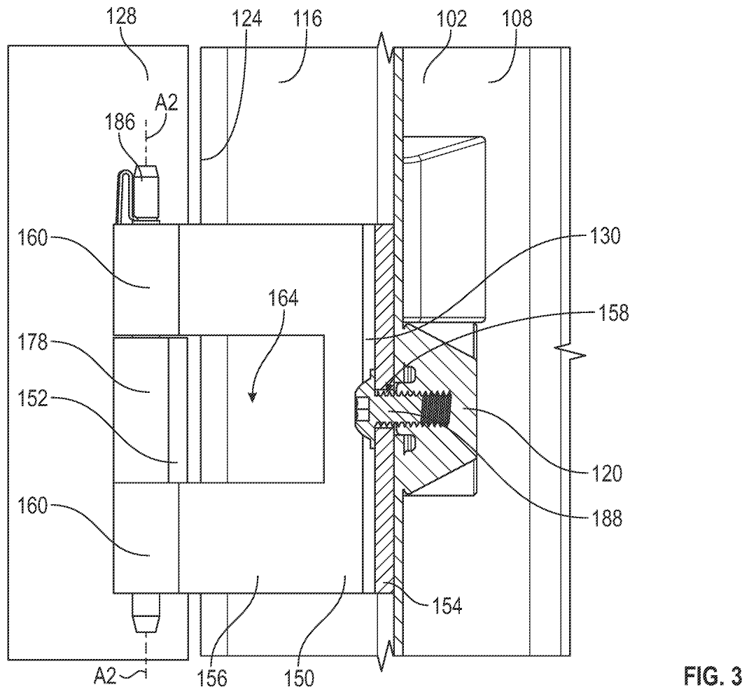

Referring now to FIG. 2A, the internal hinge 130 includes a support body 150 and a pivot body 152. The support body 150 may include various shapes and configurations, such as, but not limited to a L-shape bracket, a C-shape bracket, or the like. For example, the support body 150 illustrated in FIG. 2A shows an L-shape bracket including a support portion 154 and an extension portion 156 perpendicular to the support portion 154. The support portion 154 is positioned opposite of the external hinge 120, relative to the side wall 108. Thus, at least one securing aperture 158 of the external hinge 120 is aligned to receive a portion of a fastening mechanism (e.g., a fastener 188, see FIG. 3) and thereby secure the support body 150, through the side wall 108, at a securement hole of the external hinge 120 (see FIG. 3).

The extension portion 156 includes at least one barrel 160 disposed distal from the fixed end 162. In some embodiments, the extension portion 156 may include one or more cutout portion 164. For example, the cutout portion 164 of the extension portion 156 separates the two barrels 160 positioned at the extension portion 156 of the support body 150, although other configurations are possible.

The pivot body 152 can be pivotally supported by the support body 150 via the barrel(s) 160. In particular, in the illustrated example, the pivot body 152 includes an extension portion 170 and a connection portion 172 that is connected by a bend 174 that exhibits a first angle 176. In some embodiments, the first angle 176 defined between the extension portion 170 and the connection portion 172 about the bend 174 and may be between about 10 degrees and about 80 degrees, or between about 20 degrees and about 70 degrees, or between about 30 degrees and about 60 degrees, or between about 40 degrees and about 50 degrees. In some cases, the bend 174 may be about 45 degrees. The extension portion 170 includes a knuckle 178 that is disposed opposite and distal of the bend 174. Thus, for example, the pivot body 152 and the support body 150 may be connected by a pin 186 at the knuckle 178 and the barrels 160.

When installed for service, the connection portion 172 extends from the bend 174 to support the swing out panel 128 (see, e.g., FIG. 1). Correspondingly, for example, the connection portion 172 includes at least one fastener opening disposed between the bend 174 a second free end 184 of the connection portion 172. For example, in the illustrated example, the pivot body 152 includes a proximal fastener opening 180 and a distal fastener opening 182 disposed distal of the bend 174.

In some examples, particular distances or relative (e.g., ratios of) distances can provide particularly beneficial performance with regard to stationary support and movement of a swing out panel. Referring now to FIG. 2B, for example, a first distance D1 is defined along the extension portion 170 of the pivot body 152, between the center of the knuckle 178 and the bend 174. A second distance D2 is defined between the second free end 184 and the bend 174 along the connection portion 172 of the pivot body 152. A third distance D3 is defined between the bend 174 and (a center of) a proximal fastener opening 180 along the connection portion 172 of the pivot body 152, and a fourth distance D4 is defined between the bend 174 and (a center of) the distal fastener opening 182. (As discussed herein, distances relative to fastener openings are measured from/to a center of the relevant opening.) In some embodiments, the first distance D1 along the extension portion 170 between the knuckle 178 and the bend 174 is smaller than the second distance D2 along the connection portion 172 between the bend 174 and the second free end 184 of the connection portion 172. In some embodiments, the first distance D1 along the extension portion 170 is larger than the fourth distance D4 along the connection portion 172, between the bend 174 and the distal fastener opening 182. In some embodiments, the first distance D1 along the extension portion 170 is larger than the third distance D3 along the connection portion 172, between the bend 174 and the proximal fastener opening 180.

FIG. 3 illustrates an assembly of the external hinge 120 and the internal hinge 130 using at least on fastener 188 (e.g., a machine screw, as shown). In particular, the internal hinge 130 is within the interior volume 114 and is secured to the enclosure 100 via the external hinge 120. Thus, the external hinge 120 and the internal hinge 130 may sandwich the enclosure body 102. Referring back to FIG. 1, the external hinge 120 provides a first hinge connection between the door 122 and the enclosure body 102, enabling the door 122 to move radially about an external pin axis A1. In some examples, the door 122 includes at least one aperture (not shown) to receive a fastening mechanism (not shown) to secure one end of the external hinge 120, although other configurations are also possible. The side wall 108 also includes at least one aperture (see FIG. 3) to receive the fastening mechanism (not shown) to secure the opposite end of the external hinge 120 and the internal hinge 130, as further discussed above and below.

Referring back to FIG. 3, the internal hinge 130 provides a second hinge connection between the swing out panel 128 and the enclosure body 102 enabling the swing out panel 128 to pivot about an internal hinge pin axis A2 (see FIG. 1), from inside of the interior volume 114 to the outside of the interior volume 114. The swing out panel 128 can include at least one aperture disposed along the fixed end 132 of the swing out panel 128 to receive the fastening mechanism to secure one end of the internal hinge 130 (at least one proximal fastener opening 180 that receives at least one fastening mechanism 190, as shown in FIG. 4A).

Thus arranged, as shown in FIG. 3 in particular, the internal hinge 130 and the external hinge 120 can be secured in place on the enclosure 100 using the same fastening mechanism (e.g., the threaded fastener 188, as shown). Conventionally, installation of multiple hinges requires drilling of multiple holes, which may be undesirable for many applications of an enclosure. For example, drilling multiple holes for an electrical enclosure can create additional potential leakage paths for electrical current that may need to be addressed. In contrast, the present disclosure utilizes the same aperture that the external hinge 120 is secured through to further secure the internal hinge 130. This can reduce the number of holes that may compromise the purpose of the enclosure 100, reduce part counts by using less fastening mechanism, and eliminate the need to drill additional holes onto the enclosure 100.

FIG. 4A illustrates a swung-out orientation of the swing out panel 128 (e.g., a fully swung-out orientation), as facilitated by the geometry and other details of the internal hinge 130. As also noted above, the support body 150 of the internal hinge 130 and the pivot body 152 of the internal hinge 130 is connected by the pin 186 about the second pin axis A2, defined by the pin 186 as inserted through the barrel 160 of the support body 150 and through the knuckle 178 of the pivot body 152. The pivot body 152 can thus rotate radially about the second pin axis A2 which enables the swing out panel 128 to swing in and out of the interior volume 114. In other words, the pivot body 152 is pivotable relative to the support body 150 about the second pin axis A2.

The rotation of the swing out panel 128 is offset by the extension portion 170 of the pivot body 152 by the first distance D1. Notably, the rotational offset of the swing out panel 128 enables the swing out panel 128 to swing fully out of the interior volume 114 and the door opening 124, as can leave the door opening 124 unobstructed by the panel 128 for installation of other components through the door opening 124. Thus, thee swing out panel 128 swinging out fully from the interior volume 114 enables easy access into the interior volume 114 and access to both sides of the swing out panel 128, as needed. Correspondingly, in some embodiments, the first distance D1 (see FIG. 2B) is greater than a length of the extension portion 156 of the support body 150. Similarly, in some embodiments, the length of the extension portion 156 of the support body 150 may be smaller than the fourth distance D4 (see FIG. 2B).

In some examples, the value of the first angle 176 may be selected in particular to determine a particular installed (or service) position of the swing out panel 128 within the interior volume 114. For example, the position of the swing out panel 128 can be adjusted closer to the rear wall 112 by increasing the first angle 176 or the position of the swing out panel 128 can be adjust closer to the door opening 124 by decreasing the first angle 176. Additionally and alternatively, the change in first angle 176 may alter the length of the first distance D1 of the extension portion 170.

In some examples, the extension portion 156 of the support body 150 may extend away from the support portion 154, and beyond the front offset 125 to pivotally connect to the extension portion 170 of the pivot body 152. In other words, the extension portion 156 of the support body 150 may extend beyond the portion of the door frame 116 that is aligned with the extension portion 156 of the support body 150. The extension portion 156 may accordingly extend somewhat into the door opening 124, relative to a projection of the opening 124 perpendicularly rearward into the interior volume 114. In some examples, the extension portion 156 of the support body 150 may be spaced apart (e.g., rearward) from the front offset 125 by a gap, as shown in FIG. 4B. In other word, the extension portion 156 of the support body 150—and, correspondingly, the at least one barrel 160—can be offset inwardly into the interior volume 114, rearwardly away from the door opening 124 and the front offset 125.

Beneficially, in some examples, an internal hinge can be configured so that the hinge stops inward travel of a swing out panel with the panel at a desired orientation. For example, FIG. 4B illustrates the extension portion 156 of the support body 150 being parallel with the connection portion 172 of the pivot body 152, as can be provided by a 45 degree value for the first angle 176, for the illustrated length dimensions of the internal hinge 130. In the illustrated example, the first angle 176 defined between the extension portion 170 and the connection portion 172 of the pivot body 152 is also identical to the angle defined about the second pin axis between the extension portion 170 of the pivot body 152 and the extension portion 156 of the support body 150, although other configurations are possible. Generally, the first angle 176 can be designed so that the internal hinge 130 provides a self-stop function for the swing out panel 128.

In particular, the first angle 176 (as shown) is arranged so that contact between the extension portion 170 of the internal hinge 130 and a solid body (e.g., the support body 150, as shown) places the connection portion 172 and the panel 128 in the (closed) door 122 and the rear wall 112. In some embodiments, the swing out panel 128 being parallel with the door 122 or the rear wall 112 can provide sealing benefits by preventing unwanted substances into the interior volume 114. In some examples, including as shown, the bend 174 can contact a solid body (e.g., the support body 150) stops inward rotation of the swing out panel 128 (e.g., with the swing out panel 128 substantially parallel to the rear wall 112 of the enclosure 100 or the door opening 124). In other examples, contact with another solid body or by another part of the internal hinge 130 can provide similar functionality (e.g., with the bend 174 arranged to contact the side wall 108).

In the illustrated example, the length of the support portion 154 of the support body 150 is longer than the distance between the connection portion 172 of the pivot body 152 and the extension portion 156 of the support body 150. Thus, for the illustrated example, the bend 174 of the pivot body 152 is stopped by the support portion 154 of the support body 150 so that the (closed) door 122, the extension portion 156, the connection portion 172, and the swing out panel 128 are substantially parallel to one another and are substantially perpendicular to the at least one side wall 108, 110 of the enclosure body 102. In some examples, the length of the support portion 154 of the support body 150 may be shorter than the distance between the connection portion 172 of the pivot body 152 and the extension portion 156 of the support body 150.

In some examples, as also noted above, the bend 174 of the pivot body 152 may be in direct contact with the side wall 108 of the enclosure body 102. In some examples, contact between other components can provide a similar stop. For example, in some embodiments, the fixed end 132 of the swing out panel 128 may be in contact with the at least one side wall 108, 110 of the enclosure body 102. In some embodiments, the fixed end 132 of the swing out panel 128 may be in contact with the support portion 154 of the support body 150. In some embodiments, both the bend 174 and the fixed end 132 of the swing out panel 128 may be in contact with the at least one side wall 108,110. In some embodiments, both the bend 174 and the fixed end 132 of the swing out panel 128 may be in contact with the support portion 154 of the support body 150.

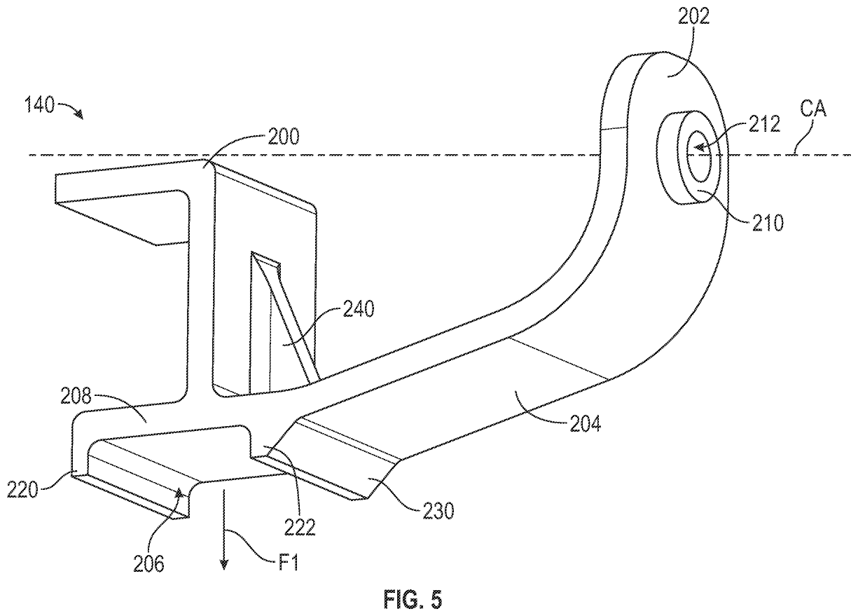

Generally, a retainer clip for a swing out panel may have various configurations, which can allow the clip to provide a handle for easy movement of the panel or to secure the panel in a desired orientation. FIG. 5 illustrates an example configuration of the retainer clip 140 that can provide a handle for users and can help to secure a panel in a particular orientation (e.g., parallel to a rear wall of an enclosure or to a front opening of the enclosure). In the illustrated example, the retainer clip 140 includes a handle portion 200, a mounting portion 202, an extension portion 204, and a clip portion 208. Generally, the handle portion 200 can provide features for easy manual (or other) engagement by users, the mounting portion 202 can be configured to secure the retainer clip 140 to a panel (see, e.g., FIG. 1), and the clip portion 208 can be configured to engage enclosure structure to temporarily secure the panel at a particular orientation. In this regard, for example, the mounting portion 202 may include a mounting ring 210 with a central aperture 212. The central aperture 212 receives a fastening mechanism (not shown) along a central axis CA and secures the retainer clip 140 onto the swing out panel 128. The extension portion 204 gradually curves outwardly away from the central axis CA, from a perspective moving from the mounting portion 202 toward the handle portion 200, which can enable an increase in bending force on the extension portion 204 from enclosure structure, as a panel is swung closed, with corresponding benefits to the ability of the retainer clip 140 to appropriately secure the panel and also to be easily released (e.g., to swing the panel out for maintenance). Thus, generally, the extension portion 204 provides an elongate, flexible cantilevered support for the handle portion 200 and the clip portion 208.

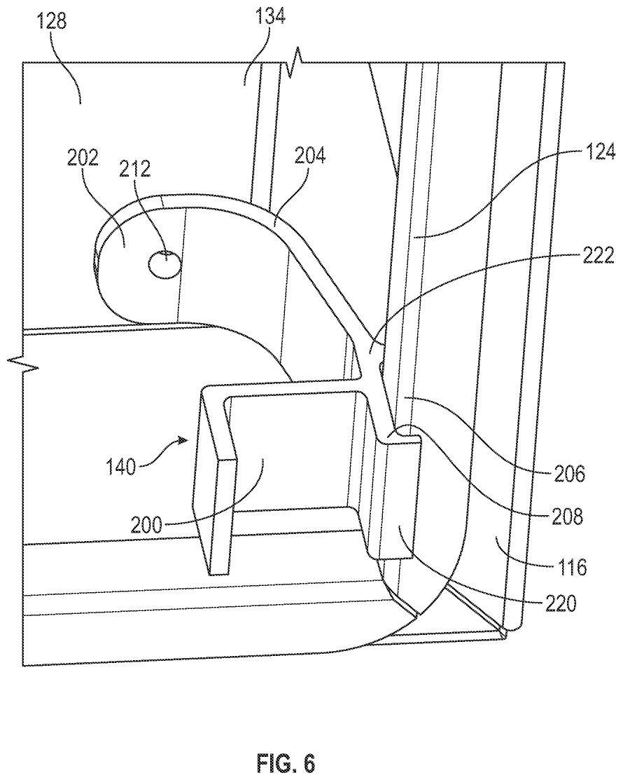

The clip portion 208 can include a recess 206 that opens in a first direction F1, as can engage a door frame or other structure on an enclosure to secure a panel in a desired orientation (see, e.g., FIG. 6). In the illustrated example, the clip portion 208 further includes an outer clip arm 220 and an inner clip arm 222 opposite of the outer clip arm 220. The outer clip arm 220 and the inner clip arm 222 are separated by the recess 206. In particular, the recess 206 is thus configured for snap engagement with the enclosure body 102 (e.g., with an extended flange of the door frame 116). In other examples, however, other configurations are possible and some clip portions can include one or more protrusions in addition to (or instead of) one or more recesses, to provide appropriately secure engagement with an enclosure structure. In some embodiments, the inner clip arm 222 may include a ramped surface 230 to help deflect the extension portion 204 as a panel is swung closed and thereby improve the ease with which the clip portion 208 can be moved into engagement with relevant enclosure structures.

As also shown in FIG. 5, the handle portion 200 can extend perpendicularly (or otherwise) away from (and opposite of) the recess 206. Thus, for example, the handle portion 200 can be spaced apart from enclosure structure to be readily engaged by a user as desired. In some embodiments, the handle portion 200 may include a rib 240 (e.g., a triangular gusset, as shown) that is positioned perpendicular to the extension portion 204 and the handle portion 200. In some examples, a handle portion may include different shapes or other different configurations. For example, as illustrated, the handle portion 200 forms an L-shaped profile. In other configurations, for example, the handle portion 200 may exhibit other geometries. For example, the handle portion 200 may sometimes include an extra rib (not shown) partially extending towards the outer clip arm 220 so that the handle portion provides a J-shaped profile to provide extra grip, or the handle portion may be curved, angled other than as shown, or otherwise differently configured.

FIG. 6 illustrates the clip portion 208 of the retainer clip 140 clasped onto the door frame 116 at the door opening 124. In some embodiments, the clip portion 208 may engaged a gasket (not shown) disposed along a periphery of the door opening 124. In some embodiments, the clip portion 208 of the retainer clip 140 can be positioned along the free end 134 of the swing out panel 128. For example, in the present disclosure, the retainer clip 140 is positioned along the free end 134 of the swing out panel 128. The positioning of the retainer clip 140 along the free end 134 can help to prevent the swing out panel 128 from bending by re-distributing stress concentrations onto the enclosure frame.

As mentioned above, the swing out panel 128 can thus be secured in parallel with the rear wall 112 (or at another desired orientation), and the four sides of the swing out panel 128 may be positioned within the interior volume 114 with relatively small tolerances (e.g., relative to the door opening 124). Further, the handle portion 200 allows the swing out panel 128 to be easily disengaged from the door frame 116 to be pulled (and thereby swung) out from the interior volume 114.

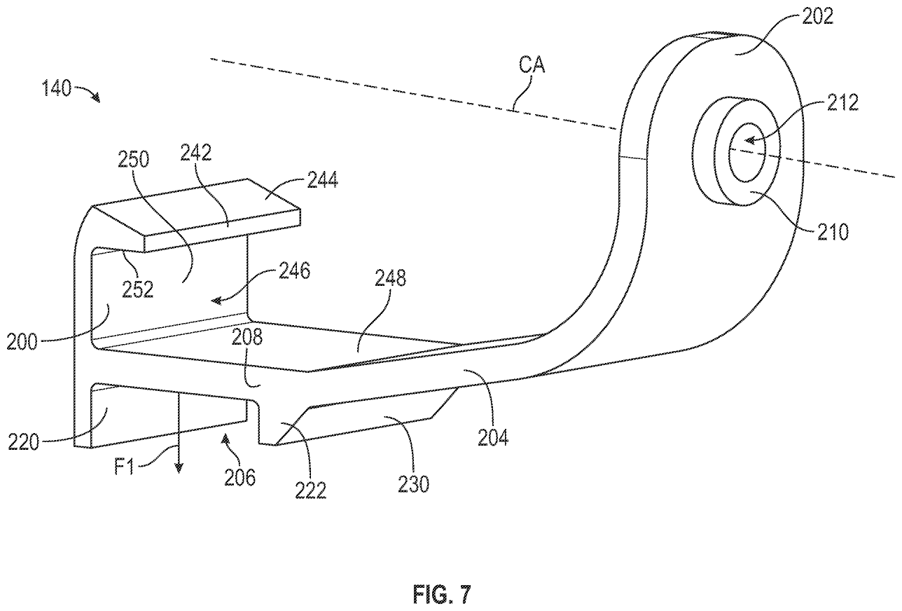

FIG. 7 illustrates an alternative configuration of the retainer clip 140. To that end, features of the retainer clip 140 include reference numbers that are generally similar to those used in FIG. 5. For example, the retainer clip 140 is described below as having a handle portion 200, a mounting portion 202, an extension portion 204, and a clip portion 208. The clip portion 208 includes a recess 206 that is defined by an outer clip arm 220 and an inner clip arm 222 and is configured to clamp onto a side wall 108, 110 of an enclosure body 102.

Unlike the retainer clip 140 of FIG. 5, the handle portion 200 of the retainer clip of FIG. 7 extends in an opposite direction of the recess 206 and the handle portion 200 extends flush with the outer clip arm 220. A distal end 242 of the handle portion includes a hook 244 that is configured to provide a gripping area 246 that is opposite of the recess 206. The gripping area 246 is defined by a first surface 248 that is defined by the extension portion 204, a second surface 250 that is defined by the handle portion 200, the second surface being orthogonal to the first surface 248, and a third surface 252 that is defined by the hook 244, the third surface 252 extending orthogonal to the second surface 250 and parallel with the first surface 248.

Thus, various embodiments of the disclosed internal hinge and related hinge system can provide benefits over conventional designs. As mentioned above, for example, an internal hinge being secured to an external hinge, using a common fastener and securement hole, can provide easier customization, including by eliminating the need to drill extra holes, and reducing the part count by reducing the number of fastening mechanisms. Additionally (or alternatively), an appropriately configured hinge can provide self-stop functionality, to prevent undesired inward or outward rotation of a swing out panel (e.g., with the swing out panel substantially parallel to a rear wall, a closed door, or a door opening). Furthermore, a clip can help to further support a swing out panel in a desired orientation (e.g., parallel with the rear wall), and can also help to secure the panel against inadvertent swing-out and also support the panel against excessive bending (e.g., by snapping into engagement with a door frame).

It is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

As used herein, unless otherwise limited or defined, discussion of particular directions is provided by example only, with regard to particular embodiments or relevant illustrations. For example, discussion of “top,” “front,” or “back” features is generally intended as a description only of the orientation of such features relative to a reference frame of a particular example or illustration. Correspondingly, for example, a “top” feature may sometimes be disposed below a “bottom” feature (and so on), in some arrangements or embodiments. Further, references to particular rotational or other movements (e.g., counterclockwise rotation) is generally intended as a description only of movement relative a reference frame of a particular example of illustration.

Also as used herein, unless otherwise limited or defined, “or” indicates a non-exclusive list of components or operations that can be present in any variety of combinations, rather than an exclusive list of components that are available only as alternatives to each other. For example, a list of A, B, or C indicates options of: A; B; C; A and B; A and C; B and C; and A, B, and C.

Further, a list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of each of A, B, and C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C. In general, the term “or” as used herein only indicates exclusive alternatives (e.g., “one or the other but not both”) when preceded by terms of exclusivity, such as “either,” “one of,” “only one of,” or “exactly one of.”

Also as used herein, unless otherwise limited or defined, “about” refers to a range of values that is within plus or minus 5% of a reference value, inclusive. For example, “about 100” indicates a range of 95 to 105, inclusive. Generally, unless otherwise noted, any references herein to a numerical range are intended to include the endpoints of the range.

Also as used herein, unless otherwise limited or defined, “substantially parallel” indicates a direction that is within ±12 degrees of a reference direction (e.g., within ±6 degrees or ±3 degrees), inclusive. Also as used herein, unless otherwise limited or defined, “substantially perpendicular” indicates a direction that is within ±12 degrees of perpendicular a reference direction (e.g., within ±6 degrees or ±3 degrees), inclusive. In this regard, a feature is substantially parallel or perpendicular to an opening if the features is substantially parallel or perpendicular, respectively, to a plane defined by the opening.

Also as used herein, unless otherwise defined or limited, ordinal numbers are used for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. An enclosure for electrical components, the enclosure comprising:
an enclosure body that defines an interior volume and a door opening;
a swing out panel to support electrical components within the interior volume; and
an internal hinge secured within the interior volume, the internal hinge rotatably supporting the swing out panel for movement between an installed orientation, in which the swing out panel is fully within the interior volume, and a swung out orientation, in which the panel extends at least partly outside of the interior volume;
the internal hinge including:
a support body including a support portion rigidly secured to a wall of the enclosure; and
a pivot body including an extension portion and a connection portion that are connected by a bend, the extension portion pivotally connected to the support body, and the connection portion extending from the bend to support the swing out panel,
the pivot body of the internal hinge, in the installed orientation, contacting one or more of the support body or the wall so that the connection portion extends one or more of substantially perpendicular to the wall or substantially parallel with the door opening.

2. The enclosure of claim 1, wherein, in the installed orientation, the bend contacts the one or more of the support body or the wall to stop rotation of the pivot body in an inward direction, relative to the door opening.

3. The enclosure of claim 2, wherein the wall is a side wall of the enclosure adjacent to a front offset of the enclosure body, the front offset defining at least one side of the door opening; and
wherein the support body further includes a support-body extension portion that extends away from the support portion, past the front offset, to pivotally connect to the extension portion of the pivot body.

4. The enclosure of claim 3, wherein the support-body extension portion is spaced rearwardly apart from the front offset to define a gap between the support-body extension portion and the front offset.

5. The enclosure of claim 1, further comprising:
a door secured to the enclosure body with an external hinge, to be pivotally movable relative to the door opening;
wherein the external hinge is outside of the interior volume and the support body of the internal hinge is secured to the enclosure via the external hinge.

6. The enclosure of claim 5, wherein the wall of the enclosure is sandwiched between the internal hinge and the external hinge.

7. The enclosure of claim 1, wherein the bend defines an angle between the extension portion and the connection portion of between about 40 degrees and about 50 degrees.

8. The enclosure of claim 1, wherein the pivot body is secured to the support body at a barrel of the pivot body, with the extension portion extending from the barrel to the bend; and
wherein a distance between the barrel and the bend is smaller than a distance between the bend and a free end of the connection portion.

9. The enclosure of claim 8, wherein the connection portion includes a distal fastener opening that secures the support body to the swing out panel; and
wherein the distance between the barrel and the bend is larger than a distance between the bend and the distal fastener opening.

10. The enclosure of claim 8, wherein the support body further includes a support- body extension portion that extends away from the support portion to pivotally connect to the extension portion of the pivot body at an extension distance away from the wall; and
wherein the connection portion includes a distal fastener opening that secures the support body to the swing out panel, in the installed orientation, at a distance away from the wall that is greater than the extension distance.

11. The enclosure of claim 1, further comprising:
a retainer clip secured at a free end of the swing out panel;
wherein the retainer clip includes an extension portion that extends away from the panel and a clip portion supported by the extension portion, the clip portion engaging the enclosure body to secure the swing out panel in the installed orientation.

12. The enclosure of claim 11, wherein the clip portion includes a first recess that opens in a first direction to engage the enclosure body and a handle portion that extends opposite the first direction to provide a handle for manual movement of the swing out panel.

13. The enclosure of claim 11, wherein the extension portion provides a flexible cantilevered support for the clip portion.

14. An enclosure for electrical components, the enclosure comprising:
an enclosure body that defines an interior volume and a door opening;
a swing out panel for support of electrical components within the interior volume; and
an internal hinge for support of a swing out panel of an enclosure, the internal hinge including:
a support body including a support portion rigidly secured to a wall of the enclosure, and a support-body extension portion extending from the support portion; and
a pivot body including a pivot-body extension portion pivotally supported by the support-body extension portion, and a connection portion that is connected to the pivot- body extension portion by a bend, the connection portion extending from the bend to support the swing out panel;
the pivot body being pivotable relative to the support body between:
an installed orientation, in which the pivot-body extension portion extends within the interior volume in an installed direction, and the connection portion supports the swing out panel within the interior volume; and
a swung out orientation, in which the pivot-body extension portion extends through the door opening in a swung out direction that is rotated by an angle of more than 180 degrees relative to the installed direction, and the connection portion supports the swing out panel outside the interior volume.

15. The enclosure of claim 14, wherein the wall is a side wall of the enclosure adjacent to a front offset of the enclosure body, the front offset defining at least one side of the door opening; and
wherein the support body further includes a support-body extension portion that extends away from the support portion, past the front offset, to pivotally connect to the pivot-body extension portion.

16. The enclosure of claim 15, wherein, in the installed orientation, the connection portion of the pivot body extends away from the side wall, past the front offset and the support- body extension portion, to support the swing out panel.

17. The enclosure of claim 14, wherein in the installed orientation, the installed direction of the pivot-body extension portion extends from the support-body extension portion inwardly into the interior volume and toward the wall of the enclosure.

18. A method of supporting electrical components in an enclosure that defines an interior volume, the method comprising:
pivoting a swing out panel on an internal hinge, through a door opening defined by an enclosure body of the enclosure, between an installed orientation, in which the swing out panel is fully within the interior volume, and a swung out orientation, in which the panel extends at least partly outside of the interior volume, the swing out panel being rotatably supported by an internal hinge secured within the interior volume, the internal hinge including: a support body including a support portion rigidly secured to a wall of the enclosure; and a pivot body including an extension portion and a connection portion that are connected by a bend, the extension portion pivotally connected to the support body, and the connection portion extending from the bend to support the swing out panel; and
supporting electrical components on the swing out panel;
the pivot body of the internal hinge, in the installed orientation, contacting one or more of the support body or the wall of the enclosure so that the connection portion extends one or more of substantially perpendicular to the wall or substantially parallel with the door opening.

19. The method of claim 18, wherein, in the installed orientation, the extension portion of the pivot body extends within the interior volume in an installed direction, and the connection portion supports the swing out panel within the interior volume; and
wherein, in the swung out orientation, the extension portion of the pivot body extends through the door opening in a swung out direction that is rotated by an angle of more than 180 degrees relative to the installed direction, and the connection portion supports the swing out panel outside the interior volume.

20. The method of claim 18, further comprising:
releasing the swing out panel from the installed orientation by disengaging from the enclosure body a clip portion of a retainer clip that is secured at a free end of the swing out panel.
